(19) United States
(12) Patent Application Publication
(10) Pub. No.: US 2025/0008815 A1
(43) Pub. Date: Jan. 2, 2025

(54) DISPLAY DEVICE

(71) Applicant: Samsung Display Co., LTD., Yongin-si (KR)

(72) Inventors: Sun-Kyu JOO, Yongin-si (KR); Cheol SHIN, Yongin-si (KR); Ho-Yong SHIN, Yongin-si (KR); Keun Chan OH, Yongin-si (KR); Dokyung YOUN, Yongin-si (KR); Kwang-Min LEE, Yongin-si (KR); Che Ho LIM, Yongin-si (KR); Woo-Man JI, Yongin-si (KR); Kang Soo HAN, Yongin-si (KR); Tae Hyung HWANG, Yongin-si (KR)

(21) Appl. No.: 18/588,698

(22) Filed: Feb. 27, 2024

(30) Foreign Application Priority Data
Jun. 29, 2023 (KR) 10-2023-0084177

(51) Int. Cl. H10K 59/80; H10K 59/122; H10K 59/38

(52) U.S. Cl. CPC H10K 59/873; H10K 59/122; H10K 59/38

(57) ABSTRACT

A display device according to an embodiment includes: a substrate including a display area and a non-display area; a transistor disposed on the substrate; a light emitting element electrically connected to the transistor; an encapsulation layer disposed on the light emitting element; a bank located on the encapsulation layer and defining an opening therein; a color conversion layer located in the opening; a filling layer located on the bank and the color conversion layer; and a transmission layer and a first spacer, which are located on the filling layer.

This application claims priority to Korean Patent Application No. 10-2023-0084177, filed on Jun. 29, 2023, and all the benefits accruing therefrom under 35 U.S.C. § 119, the content of which in its entirety is herein incorporated by reference.

### BACKGROUND

### (a) Field

The present disclosure relates to a display device.

### (b) Description of the Related Art

A light emitting element is a device that emits light when an exciton is formed and stabilized within the light emitting layer formed between the anode and the cathode, where holes supplied from the anode and electrons supplied from the cathode combine.

Since light emitting elements have advantages such as a wide viewing angle, fast response speed, thin thickness, and low power consumption, they are widely applied to various electric and electronic devices such as televisions, monitors, and mobile phones.

A display device including a color conversion layer has been proposed in order to implement a high-efficiency display device.

The color conversion layer may convert incident light into a different color.

### SUMMARY

Embodiments are intended to provide a display device having a spacer and a transmission layer formed on an upper substrate, thereby preventing the occurrence of cracks in a manufacturing process and having improved reliability.

A display device according to an embodiment includes: a substrate including a display area and a non-display area; a transistor disposed on the substrate; a light emitting element electrically connected to the transistor; an encapsulation layer disposed on the light emitting element; a bank located on the encapsulation layer and defining an opening; a color conversion layer located in the opening; a filling layer located on the bank and the color conversion layer; and a transmission layer and a first spacer, which are located on the filling layer.

The opening may include a first opening, a second opening, and a third opening, and the color conversion layer may include: a first color conversion layer positioned in the first opening and including quantum dots; and a second color conversion layer positioned within the second opening and including quantum dots.

The transmission layer may overlap the third opening in a thickness direction of the substrate.

The filling layer may be positioned in the third opening.

The transmission layer and the first spacer may include the same type of scatterer.

The heights of the transmission layer and the first spacer in the thickness direction may be the same.

The display device may further include: a second spacer positioned in the non-display area, and a sealant overlapping the second spacer in the thickness direction.

The second spacer may have the same height as the transmission layer, and the second spacer and the transmission layer may include the same type of scatterer.

The display device may further include: an insulating layer positioned on the transmission layer, the first spacer, and the filling layer, and a color filter positioned on the insulating layer.

The color filter includes: a first color filter overlapping the transmission layer in the thickness direction; a second color filter overlapping the first color conversion layer in the thickness direction; and a third color filter overlapping the second color conversion layer in the thickness direction, and the bank may overlap at least two of the first color filter, the second color filter, and the third color filter in the thickness direction.

At least one of the first spacer and the second spacer may overlap at least two of the first color filter, the second color filter, and the third color filter in the thickness direction.

A display device according to an embodiment includes: a substrate including a display area and a non-display area; a transistor disposed on the substrate; a light emitting element electrically connected to the transistor; an encapsulation layer disposed on the light emitting element; a bank located on the encapsulation layer and defining an opening therein; a color conversion layer located in the opening; a filling layer located on the bank and the color conversion layer; and a first transmission layer, a second transmission layer, and a first spacer, which are disposed on the filling layer.

The opening may include a first opening, a second opening, and a third opening, and the color conversion layer may include a first color conversion layer positioned within the first opening.

The second opening may overlap the second transmission layer in a thickness direction of the substrate, and the third opening may overlap the first transmission layer in the thickness direction.

The filling layer may fill the second opening and the third opening.

The display device may further include: an insulating layer positioned on the first transmission layer, the second transmission layer, and the filling layer; and a color filter positioned on the insulating layer.

The first transmission layer, the second transmission layer, and the first spacer may have the same height and include the same type of scatterer.

The display device may further include a second spacer positioned in the non-display area and a sealant overlapping the second spacer in the thickness direction.

The second spacer may have the same height as the first spacer and may include the same type of scatterer.

The light emitting element may emit a mixture of blue light and green light.

According to embodiments, a display device having improved reliability and effectively preventing cracks generated in a manufacturing process may be provided by providing a display device having a spacer and a transmission layer disposed on an upper substrate.

### BRIEF DESCRIPTION OF THE DRAWINGS

FIG. 1 is a schematic exploded perspective view of a display device according to an embodiment.

FIG. 2 is a schematic cross-sectional view of a display panel according to an embodiment.

FIG. 3, FIG. 4, and FIG. 5 are cross-sectional views of a display panel according to an embodiment.

### DETAILED DESCRIPTION

Hereinafter, with reference to the accompanying drawings, various embodiments will be described in detail so that those skilled in the art can easily carry out the present invention.

This invention may be embodied in many different forms and is not limited to the embodiments set forth herein.

In order to clearly describe the present invention, parts irrelevant to the description are omitted, and the same reference numerals are assigned to the same or similar components throughout the specification.

In addition, since the size and thickness of each component shown in the drawings are arbitrarily shown for convenience of explanation, the present invention is not necessarily limited to that which is shown.

In the drawings, the thickness is shown enlarged to clearly express the various layers and regions.

And in the drawings, for convenience of explanation, the thicknesses of some layers and regions are exaggerated.

In addition, when a part such as a layer, film, region, or plate is said to be “above” or “on” another part, this includes not only the case where it is “directly on” the other part, but also the case where another part exists in the middle thereof.

Conversely, when a part is said to be “directly on” another part, it means that there is no other part in between.

In addition, being “above” or “on” a reference part means being located above or below the reference part, and does not necessarily mean being located “above” or “on” it in the opposite direction of gravity.

In addition, throughout the specification, when a certain component is said to “include,” it means that it may further include other components without excluding other components unless otherwise stated.

Also, throughout the specification, when reference is made to a “planar image,” it means when the target part is viewed from above, and when reference is made to a “cross-sectional image,” it means when the cross-section of the target part cut vertically is viewed from the side.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

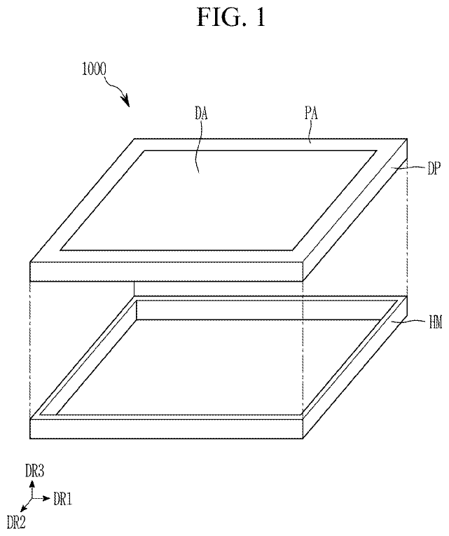

Hereinafter, a display device according to an embodiment will be described with reference to FIG. 1.

FIG. 1 is a schematic exploded perspective view of a display device according to an embodiment.

Referring to FIG. 1, a display device 1000 according to an embodiment may include a display panel DP and a housing HM.

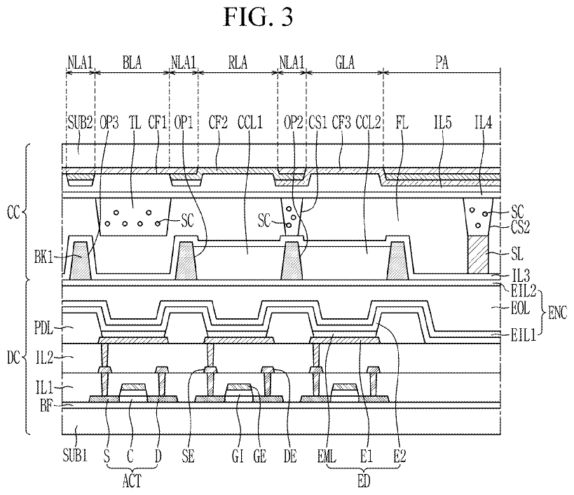

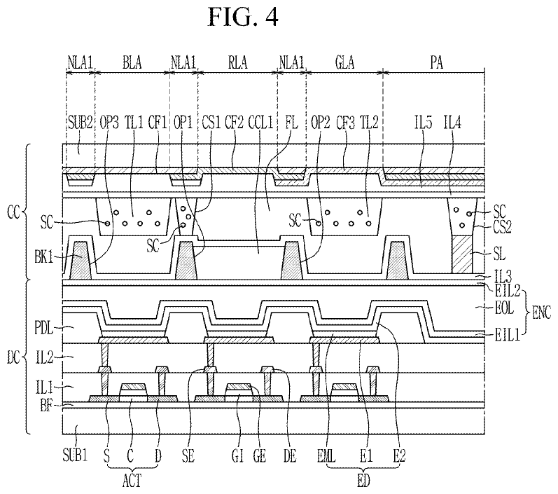

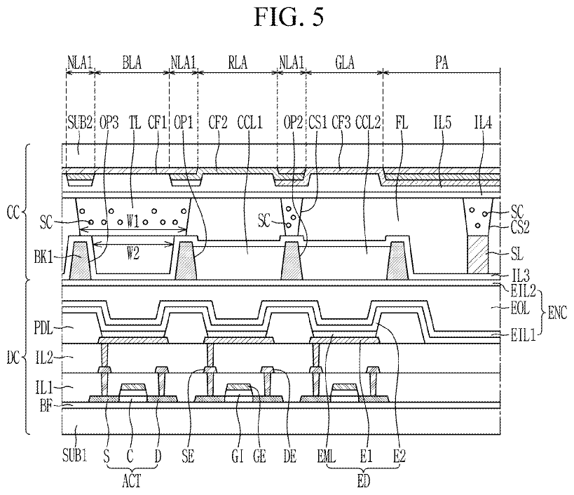

A surface of the display panel DP on which an image is displayed is parallel to a surface defined by the first and second directions DR1 and DR2. The third direction DR3 indicates a normal direction of the surface on which an image is displayed—that is, a thickness direction of the display panel DP or a first substrate SUB1 (See FIG. 3). The front surface (or upper surface) and rear surface (or lower surface) of each member are divided by the third direction DR3. However, directions indicated by the first to third directions DR1, DR2, and DR3 may be converted into other directions in a relative concept.

The display panel DP may be a flat rigid display panel, but it is not limited thereto and may also be a flexible display panel in another embodiment. The display panel DP may be formed of or including an organic light emitting display panel. However, the type of display panel DP is not limited thereto, and may include various types of panels. For example, the display panel DP may include a liquid crystal display panel, an electrophoretic display panel, an electrowetting display panel, and the like. Also, the display panel DP may be formed of a next-generation display panel such as a micro-light emitting diode display panel, a quantum dot light emitting diode display panel, and a quantum dot organic light emitting diode display panel. A micro-LED display panel is formed in such a way that each pixel is composed of light emitting diodes having a size of 10 to 100 micrometers. Such a micro-light emitting diode display panel has advantages such as the use of inorganic materials, omission of a backlight, fast response speed, high luminance with low power consumption, and the ability not to break when bent. A quantum dot light emitting diode display panel is formed by attaching a film containing quantum dots or forming a material containing quantum dots. Quantum dots are composed of inorganic materials such as indium and cadmium, and refer to particles that emit light by themselves and have a diameter of several nanometers or less. By adjusting the particle size of the quantum dots, light of a desired color can be displayed.

The quantum dot organic light emitting diode display panel uses a blue organic light emitting diode as a light source, attaches a film containing red and green quantum dots on it, or deposits a material containing red and green quantum dots to realize color.

The display panel DP according to an embodiment may include other various display panels.

As shown in FIG. 1, the display panel DP includes a display area DA where an image is displayed and a non-display area PA adjacent to the display area DA. The non-display area PA is an area where no image is displayed. The display area DA may have a rectangular shape, for example, and the non-display area PA may have a shape surrounding the display area DA. However, the shapes of the display area DA and the non-display area PA may be relatively designed without being limited thereto.

The housing HM provides an inner space. The display panel DP is mounted inside the housing HM. In addition to the display panel DP, various electronic components such as a power supply unit, a storage device, and an audio input/output module may be mounted inside the housing HM.

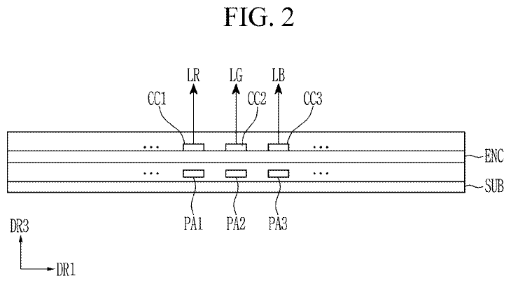

Hereinafter, a display area of a display panel according to an embodiment will be described with reference to FIG. 2.

FIG. 2 is a schematic cross-sectional view of a display panel according to an embodiment.

Referring to FIG. 2, a plurality of pixels PA1, PA2, and PA3 may be disposed on the substrate SUB corresponding to the display area DA of FIG. 1. Each of the pixels PA1, PA2, and PA3 may include a plurality of transistors and light emitting elements connected thereto. An encapsulation layer ENC may be positioned on the plurality of pixels PA1, PA2, and PA3.

The display area DA may be protected from outside air or moisture through the encapsulation layer ENC.

The encapsulation layer ENC may be integrally provided to overlap the entire surface of the display area DA in a thickness direction of the substrate SUB, and may also be partially disposed on the non-display area PA.

A first color conversion part CC1, a second color conversion part CC2, and a transmission part CC3 may be positioned on the encapsulation layer ENC. The first color conversion part CC1 may overlap the first pixel PA1, the second color conversion part CC2 may overlap the second pixel PA2, and the transmission part CC3 may overlap the third pixel PA3 in the thickness direction.

Light emitted from the first pixel PA1 may pass through the first color conversion unit CC1 to provide red light LR. Light emitted from the second pixel PA2 may pass through the second color conversion unit CC2 to provide green light LG. Light emitted from the third pixel PA3 may pass through the transmission part CC3 to provide blue light LB.

Hereinafter, a structure of a display panel according to an embodiment will be described in more detail with reference to FIG. 3 and FIG. 4. FIG. 3 and FIG. 4 are cross-sectional views of a display panel according to an embodiment.

First, referring to FIG. 3, the display area DA according to an embodiment includes a red light emitting area RLA, a green light emitting area GLA, and a blue light emitting area BLA.

A non-emission area NLA1 may be positioned between the red light emitting area RLA, the green light emitting area GLA, and the blue light emitting area BLA.

Each light emitting area may correspond to a pixel. For example, the blue light emitting area BLA, the red light emitting area RLA, and the green light emitting area GLA may correspond to a blue pixel, a red pixel, and a green pixel, respectively.

A cross-sectional structure of the display area DA will be described below.

The display unit DC according to an embodiment includes a first substrate SUB1. The first substrate SUB1 may include a flexible material such as plastic that can be easily bent, folded, or rolled.

A buffer layer BF may be positioned on the first substrate SUB1. The buffer layer BF may include silicon nitride (SiNₓ), silicon oxide (SiO₂), or silicon oxynitride (SiOxNy).

The buffer layer BF is positioned between the first substrate SUB1 and a semiconductor layer ACT to block impurities from the first substrate SUB1 during a crystallization process to form polycrystalline silicon, thereby improving the characteristics of the polycrystalline silicon. Stress on the semiconductor layer ACT formed on the buffer layer BF may be relieved by planarizing the first substrate SUB1.

The semiconductor layer ACT is positioned on the buffer layer BF. The semiconductor layer ACT may be formed of or including polycrystalline silicon or an oxide semiconductor. The semiconductor layer ACT includes a channel region C, a source region S, and a drain region D. The source region S and the drain region D are disposed on opposite sides of the channel region C, respectively. The channel region C is an intrinsic semiconductor not doped with impurities, and the source region S and drain region D are impurity semiconductors doped with conductive impurities.

The semiconductor layer ACT may be formed of or including an oxide semiconductor, and in this case, a separate protective layer (not shown) may be added to protect the oxide semiconductor material that is vulnerable to an external environment such as high temperature.

A gate insulating layer GI is positioned on the semiconductor layer ACT.

The gate insulating layer GI may be a single layer or a multi-layer including at least one of silicon nitride (SiNₓ), silicon oxide (SiO₂), and silicon oxynitride (SiOxNy).

A gate electrode GE is positioned on the gate insulating layer GI. The gate electrode GE includes one of copper (Cu), a copper alloy, aluminum (Al), an aluminum alloy, molybdenum (Mo), and a molybdenum alloy. It may be a multi-layer in which metal layers are to be laminated.

An interlayer-insulating layer IL1 is positioned on the gate electrode GE and the gate insulating layer GI. The interlayer-insulating layer IL1 may include silicon nitride (SiNₓ), silicon oxide (SiO₂), or silicon oxynitride (SiOxNy).

An opening exposing the source region S and the drain region D is positioned in the interlayer-insulating layer IL1.

A source electrode SE and a drain electrode DE are positioned on the interlayer-insulating layer IL1. The source electrode SE and the drain electrode DE are connected to the source region S and the drain region D, respectively, of the semiconductor layer ACT through an opening defined in the interlayer-insulating layer IL1.

A passivation layer IL2 is positioned on the interlayer-insulating layer IL1, the source electrode SE, and the drain electrode DE. Since the passivation layer IL2 covers and flattens the interlayer-insulating layer IL1, the source electrode SE, and the drain electrode DE, a first electrode E1 may be formed without a step on the passivation layer IL2.

The passivation layer IL2 may be made of an organic material such as polyacrylate resin or polyimide resin, or a laminated layer of an organic material and an inorganic material.

The first electrode E1 is positioned on the passivation layer IL2. The first electrode E1 is connected to the drain electrode DE through the opening of the passivation layer IL2.

The driving transistor, including the gate electrode GE, the semiconductor layer ACT, the source electrode SE, and the drain electrode DE, is connected to the first electrode E1 to supply a driving current to the light emitting element ED.

The display device according to the present embodiment may further include a switching transistor (not shown) that is connected to a data line and delivers data voltage in response to a scan signal, in addition to the driving transistor shown in FIG. 3 and FIG. 4, and a compensation transistor (not shown) that is connected to the driving transistor and compensates for the threshold voltage of the driving transistor in response to the scan signal.

A pixel defining layer PDL may be positioned on the passivation layer IL2 and the first electrode E1, and the pixel defining layer PDL may define a pixel opening overlapping the first electrode E1 in the thickness direction and defining an emission area.

The pixel defining layer PDL may include an organic material such as polyacrylate resin or polyimide resin or a silica-based inorganic material.

The pixel opening may have a planar shape substantially similar to the shape of the first electrode E1, and may have a rhombus or an octagonal shape similar to the rhombus in a plan view (i.e., view in the thickness direction), but is not limited thereto and may have any shape such as a quadrangle or a polygon in another embodiment.

A light emitting layer EML is positioned on the first electrode E1 overlapping the pixel opening in the thickness direction.

The light emitting layer EML may be formed of or including a low-molecular-weight organic material or a high-molecular-weight organic material such as poly 3,4-ethylenedioxythiophene (“PEDOT”).

In addition, the light emitting layer EML may be a multi-layer including one or more layer selected from among a hole injection layer HIL, a hole transporting layer HTL, an electron transporting layer ETL, and an electron injection layer EIL.

Most of the light emitting layer EML may be positioned within the pixel opening, and may also be positioned on a side surface or above the pixel defining layer PDL.

A second electrode E2 is positioned on the light emitting layer EML.

The second electrode E2 may be positioned over a plurality of pixels, and may receive a common voltage through a common voltage transfer unit (not shown) in the non-display area.

The first electrode E1, the light emitting layer EML, and the second electrode E2 may constitute the light emitting element ED.

Here, the first electrode E1 may be an anode that is a hole injection electrode, and the second electrode E2 may be a cathode that is an electron injection electrode.

However, the embodiment is not necessarily limited thereto, and the first electrode E1 may serve as a cathode and the second electrode E2 may serve as an anode according to a driving method of the organic light emitting display device.

Holes and electrons are injected into the light emitting layer (“EML”) from the first electrode E1 and the second electrode E2, respectively, and when the excitons in which the injected holes and electrons fall from the excited state to the ground state, light emission occurs.

The encapsulation layer ENC is positioned on the second electrode E2.

The encapsulation layer ENC may cover not only the upper surface but also the side surfaces of the display layer including the light emitting element ED, thereby sealing the display layer.

Since the light emitting element is very vulnerable to moisture and oxygen, the encapsulation layer ENC seals the display layer to block inflow of external moisture and oxygen.

The encapsulation layer ENC may include a plurality of layers, and may be formed of or including a composite layer including both an inorganic layer and an organic layer, including a first inorganic layer EIL1, an organic layer EOL, and a second inorganic layer.

A color conversion unit CC is positioned on the encapsulation layer ENC.

The color conversion unit CC includes a second substrate SUB2 overlapping the first substrate SUB1 in the thickness direction.

The second substrate SUB2 may include a flexible material such as plastic that can be easily bent, folded, or rolled.

The color conversion unit CC may include a bank BK1 positioned on the encapsulation layer ENC.

The bank BK1 may define a first opening OP1, a second opening OP2, and a third opening OP3 overlapping the pixel opening in the thickness direction.

The sizes of the first opening OP1, the second opening OP2, and the third opening OP3 may be different or the same.

The first color conversion layer CCL1 may be positioned in the first opening OP1.

The first color conversion layer CCL1 may convert supplied light into red light.

The first color conversion layer CCL1 may include quantum dots.

The second color conversion layer CCL2 may be positioned in the second opening OP2.

The second color conversion layer CCL2 may convert supplied light into green light.

The second color conversion layer CCL2 may include quantum dots.

Then, the quantum dots will be described in detail below.

In this specification, quantum dots (also referred to as semiconductor nanocrystals) may include II-VI group compounds, III-V group compounds, IV-VI group compounds, group IV elements or compounds, I-III-VI group compounds, II-III-VI group compounds, I-II-IV-VI group compounds, or combinations thereof.

The group II-VI compounds can be selected from binary compounds consisting of CdSe, CdTe, ZnS, ZnSe, ZnTe, ZnO, HgS, HgSe, HgTe, MgSe, MgS and their mixtures; ternary compounds selected from a group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and their mixtures; and quaternary compounds selected from a group consisting of HgZnTeS, CdZnSeS, CdZnSeTe, CdZnSTe, CdHgSeS, CdHgSeTe, CdHgSTe, HgZnSeS, HgZnSeTe, HgZnSTe and their mixtures.

The group II-VI compound may further include a group III metal.

The group III-V compound is a binary element compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and mixtures thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and mixtures thereof.

The group III-V compound may further include a group II metal (e.g., InZnP).

The group IV-VI compound is a binary element compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and it may be selected from the group consisting of quaternary compounds selected from the group consisting of SnPbSSe, SnPbSeTe, SnPbSTe, and mixtures thereof.

The group IV element or compound is a monoatomic compound selected from the group consisting of Si, Ge, and combinations thereof; and it may be selected from the group consisting of a binary element compound selected from the group consisting of SiC, SiGe, and combinations thereof, but is not limited thereto.

Examples of the group I-III-VI compound include, but are not limited to, CuInSe2, CuInS2, CuInGaSe, and CuInGaS. Examples of the group I-II-IV-VI compound include, but are not limited to, CuZnSnSe and CuZnSnS. The group IV element or compound is an element selected from the group consisting of Si, Ge, and mixtures thereof; and it may be selected from the group consisting of a binary element compound selected from the group consisting of SiC, SiGe, and mixtures thereof.

The group II-III-VI compound is ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe; and it may be selected from the group consisting of HgInTe, MgGaS, MglS, MgInS, MgGaSe, MgAlSe, MgInSe, and combinations thereof, but is not limited thereto.

The group I-II-IV-VI compound may be selected from CuZnSnSe and CuZnSnS, but is not limited thereto.

In one embodiment, the quantum dots may not include cadmium. Quantum dots may include semiconductor nanocrystals based on group III-V compounds including indium and phosphorus.

The group III-V compound may further include zinc. Quantum dots may include semiconductor nanocrystals based on group II-VI compounds including zinc and a chalcogen element (e.g., sulfur, selenium, tellurium, or combinations thereof).

Among the quantum dots, the above-mentioned two-element compound, three-element compound, and/or quaternary element compound may be present in a particle at a uniform concentration, or may be present in the same particle with partially different concentration distributions.

Also, one quantum dot may have a core/shell structure surrounding another quantum dots. The interface between the core and the shell may have a concentration gradient in which the concentration of elements present in the shell decreases toward the center. In some embodiments, the quantum dots may have a core-shell structure including a core including the aforementioned nanocrystal and a shell surrounding the core.

The shell of the quantum dots may serve as a protective layer for maintaining semiconductor properties by preventing chemical denaturation of the core and/or as a charging layer for imparting electrophoretic properties to the quantum dots.

The shell may be monolayer or multi-layer.

The interface between the core and the shell may have a concentration gradient in which the concentration of elements present in the shell decreases toward the center.

Examples of the quantum dot shell include metal or non-metal oxides, semiconductor compounds, or combinations thereof.

For example, the metal or nonmetal oxide may be SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or a binary element compound such as MgAl₂O₄, CoFe₂O₄, NiFe₂O₄, CoMn₂O₄ and the like can be exemplified, but the present invention is not limited thereto.

In addition, examples of the semiconductor compound include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and the like. However, the present invention is not limited thereto.

The interface between the core and the shell may have a concentration gradient in which the concentration of elements present in the shell decreases toward the center.

In addition, the semiconductor nanocrystal may have a structure including one semiconductor nanocrystal core and a multi-layered shell surrounding the semiconductor nanocrystal core.

In one embodiment, the multi-layer shell can have two or more layers, such as two, three, four, five, or more layers.

Two adjacent layers of the shell may have a single composition or different compositions.

Each layer in the multi-layer shell may have a composition that varies along a radius.

Quantum dots may have a full width of half maximum (“FWHM”) of the emission wavelength spectrum of about 45 nanometers (nm) or less, preferably about 40 nm or less, and more preferably about 30 nm or less, and thus color purity or color reproducibility in this range can be effectively improved.

In addition, since light emitted through the quantum dots is emitted in all directions, a wide viewing angle may be improved.

In the quantum dots, the shell material and the core material may have different energy band gaps.

For example, the energy band gap of the shell material may be larger than the energy band gap of the core material.

In other embodiments, the energy band gap of the shell material may be smaller than the energy band gap of the core material. The quantum dots may have multi-layered shells. In a multi-layered shell, the energy band gap of the outer layers may be larger than the energy band gap of the inner layers (i.e., layers closer to the core). In a multi-layered shell, the energy band gap of the outer layers may be smaller than the energy band gap of the inner layers.

Quantum dots can control the absorption/emission wavelength by adjusting the composition and size. The maximum emission peak wavelength of the quantum dots may have a wavelength range of ultraviolet to infrared wavelengths or higher.

Quantum dots can have a quantum efficiency of about 10% or more, such as about 30% or more, about 50% or more, about 60% or more, about 70% or more, about 90% or more, or even 100%.

Quantum dots can have a relatively narrow spectrum. The quantum dots may have, for example, a full width of half maximum of an emission wavelength spectrum of about 50 nm or less, such as about 45 nm or less, about 40 nm or less, or about 30 nm or less.

The quantum dots may have a particle size of about 1 nm or more and about 100 nm or less. The size of the particle refers to the diameter of the particle or a diameter converted from a two-dimensional image obtained by transmission electron microscopy assuming a spherical shape.

The quantum dots can have a size of about 1 nm to about 20 nm-for example, 2 nm or more, 3 nm or more, or 4 nm or more and 50 nm or less, 40 nm or less, 30 nm or less, 20 nm or less, 15 nm or less and 10 nm or less.

The shape of the quantum dots is not particularly limited. For example, the shape of the quantum dot may include, but is not limited to, a sphere, a polyhedron, a pyramid, a multiped, a square, a cuboid, a nanotube, a nanorod, a nanowire, a nanosheet, or a combination thereof.

Quantum dots are commercially available or can be suitably synthesized. The particle size of the quantum dots can be controlled relatively freely, and the particle size can be uniformly controlled during colloidal synthesis.

The quantum dots may include an organic ligand (e.g., having a hydrophobic moiety and/or a hydrophilic moiety). The organic ligand moiety may be bound to the surface of the quantum dots.

The organic ligand includes RCOOH, RNH₂, R₂NH, R₃N, RSH, R₃PO, R₃P, ROH, RCOOR, RPO(OH)₂, RHPOOH, R₂POOH, or a combination thereof, wherein each R is independently C3 to C40 (e.g., C5 or more and C24 or less) substituted or unsubstituted alkyl, substituted or unsubstituted alkenyl, etc., or C3 to C40 substituted or unsubstituted aliphatic hydrocarbon group, substituted or unsubstituted C6 to C40 aryl group, it may be a substituted or unsubstituted aromatic hydrocarbon group of C6 to C40 (e.g., C6 or more and C20 or less), or a combination thereof.

Examples of the organic ligand include thiol compounds such as methane thiol, ethane thiol, propane thiol, butane thiol, pentane thiol, hexane thiol, octane thiol, dodecane thiol, hexadecane thiol, octadecane thiol, and benzyl thiol; methane amine, ethane amine, propane amine, butane amine, pentyl amine, hexyl amine, octyl amine, nonylamine, decylamine, dodecyl amine, hexadecyl amine, octadecyl amine, dimethyl amine, diethyl amine, dipropyl amine, amines such as tributylamine and trioctylamine;

carboxylic acid compounds such as methane acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, and benzoic acid; phosphine compounds such as methyl phosphine, ethyl phosphine, propyl phosphine, butyl phosphine, pentyl phosphine, octylphosphine, dioctylphosphine, tributylphosphine, and trioctylphosphine; phosphines such as methyl phosphine oxide, ethyl phosphine oxide, propyl phosphine oxide, butyl phosphine oxide, pentyl phosphine oxide, tributylphosphine oxide, octylphosphine oxide, dioctyl phosphine oxide, and trioctylphosphine oxide compound or its oxide compound; diphenyl phosphine, triphenyl phosphine compounds or oxide compounds thereof; C5 to C20 alkyl phosphinic acids such as hexylphosphinic acid, octylphosphinic acid, dodecane phosphinic acid, tetradecane phosphinic acid, hexadecane phosphinic acid and octadecane phosphinic acid, C5 to C20 alkyl phosphonic acids; and the like, but are not limited thereto. Quantum dots may include a hydrophobic organic ligand alone or they may be in a mixture of one or more. The hydrophobic organic ligand may not include a photopolymerizable moiety (e.g., an acrylate group or a methacrylate group).

A first insulating layer IL3 may be positioned on the bank BK1, the first color conversion layer CCL1, and the second color conversion layer CCL2.

The first insulating layer IL3 may cover the bank BK1, the first color conversion layer CCL1, and the second color conversion layer CCL2. The first insulating layer IL3 may include at least one of silicon nitride, silicon oxide, and silicon oxynitride. According to an embodiment, the first insulating layer IL3 may be omitted.

A filling layer FL may be positioned on the first insulating layer IL3. The filling layer FL may combine components positioned on the first substrate SUB1 and components positioned on the second substrate SUB2. One display panel may be formed through the filling layer FL. The filling layer FL may fill the third opening OP3.

Although the present specification shows an embodiment in which the filling layer FL includes a separate filler, the space is not limited thereto and the corresponding space may be filled with air without the filling layer FL in another embodiment.

That is, in the embodiment of FIG. 3, an air may be substituted for the position of the filling layer FL.

When the corresponding space is filled with air, the refractive index of the corresponding space has the refractive index of air (approximately 1), and thus may serve as a low-refractive index layer.

Through this, light emission efficiency may be effectively improved.

The transmission layer TL and a first spacer CS1 may be positioned on the filling layer FL. The transmission layer TL may overlap the third opening OP3 in the thickness direction. The transmission layer TL may be positioned in a portion corresponding to the blue light emitting area BLA partitioned by the bank BK1.

The transmission layer TL may be formed on the second substrate SUB2 during the manufacturing process and may be coupled to the first substrate SUB1 through the filling layer FL. The transmission layer TL may have a tapered cross-section toward the first substrate SUB1. That is, a width of the transmission layer TL in a direction perpendicular to the thickness direction of the first substrate SUB1 may reduce in a direction toward the first substrate SUB1.

The transmission layer TL may include a scatterer SC. The scatterer SC may be one or more selected from the group consisting of SiO₂, BaSO₄, Al₂O₃, ZnO, ZrO₂, and TiO₂.

The transmission layer TL may include a polymer resin and the scatterer included in the polymer resin. For example, the transmission layer TL may include TiO₂, but is not limited thereto.

The transmission layer TL may transmit light incident from the light emitting element ED.

In the display panel according to the present embodiment, the first color conversion layer CCL1 color-converts the incident light to red light and emits it. In addition, the second color conversion layer CCL2 color-converts incident light to green light and emits it. However, light incident on the transmission layer TL is transmitted without color conversion. Incident light may include blue light. The incident light may be blue light alone or a mixture of blue light and green light. Alternatively, blue light, green light, and red light may all be included.

The color conversion unit CC according to an embodiment includes the first spacer CS1. The first spacer CS1 may maintain a gap between components in a process of bonding the second substrate SUB2 and the first substrate SUB1.

The first spacer CS1 may be positioned between the first insulating layer IL3 and the second insulating layer IL4. The first spacer CSI may overlap the bank BK1 and the pixel defining layer PDL in the thickness direction. The first spacer CS1 may be positioned on the same layer as the transmission layer TL. The first spacer CS1 may be formed in the same process as the transmission layer TL.

The first spacer CS1 and the transmission layer TL may include the same material. The first spacer CS1 and the transmission layer TL may include the same type of scatterer SC. The height of the first spacer CS1 and the height of the transmission layer TL may be the same.

The first spacer CS1 may have a tapered shape toward the first substrate SUB1.

When the first spacer CSI and the transmission layer TL have a first height and a first scatterer content, the value of the first height multiplied by first scatterer content may be maintained constant. The first height may be about 0.5 micrometers to about 10 micrometers—for example, about 1 micrometer to about 5 micrometers. It is assumed that the first spacer CS1 and the transmission layer TL have a height of 4 micrometers and a scatterer content of 3 percentages by weight (wt %). When the first spacer CS1 and the transmission layer TL are modified to have a height of 3 micrometers, the first spacer CS1 and the transmission layer TL are modified to have a scatterer content of 4 wt %. Here, the “height” of an object means a thickness of the object in the thickness direction of the first substrate SUB1.

Within the range where the value of the height multiplied by scatterer content of the first spacer CS1 and the transmission layer TL is maintained constant, the height and scatterer content of the first spacer CS1 and the transmission layer TL can change.

A second insulating layer IL4 may be positioned on the transmission layer TL, the first spacer CS1, and the filling layer FL. The second insulating layer ILA may include, for example, silicon nitride (SiNₓ), silicon oxide (SiO2), or silicon oxynitride (SiOxNy). In some embodiments, the second insulating layer IL4 may be omitted.

A third insulating layer IL5 may be positioned on the second insulating layer IL4. The third insulating layer IL5 may include, for example, an organic material or an inorganic material such as silicon nitride (SiNₓ), silicon oxide (SiO2), or silicon oxynitride (SiOxNy).

The color conversion unit CC includes a first color filter CF1, a second color filter CF2, and a third color filter CF3 positioned between the second substrate SUB2 and the display unit DC.

The first color filter CF1 may overlap the transmission layer TL in the thickness direction. The first color filter CF1 transmits the blue light that has passed through the transmission layer TL and absorbs light of other wavelengths, thereby increasing the purity of the blue light emitted to the outside of the display device.

The second color filter CF2 may overlap the first color conversion layer CCL1 in the thickness direction. The second color filter CF2 transmits red light that has passed through the first color conversion layer CCL1 and absorbs light of other wavelengths, thereby increasing the purity of the red light emitted to the outside of the display device.

The third color filter CF3 may overlap the second color conversion layer CCL2 in the thickness direction. The third color filter CF3 transmits the green light that has passed through the second color conversion layer CCL2 and absorbs light of other wavelengths, thereby increasing the purity of the green light emitted to the outside of the display device.

At least two of the third color filter CF3, the second color filter CF2, and the first color filter CF1 may overlap in the non-emission area NLA1 in the thickness direction to serve as a light blocking member.

The non-emission area NLA1 may overlap the pixel defining layer PDL of the display unit DC and the bank BK1 of the color conversion unit CC in the thickness direction. In the non-display area PA, a buffer layer BF located on the first substrate SUB1 and extending from the display area DA, an interlayer-insulating layer IL1, a passivation layer IL2, a second electrode E2, an encapsulation layer ENC, the first insulating layer IL3, the second insulating layer IL4, and the third insulating layer IL5 are positioned. At least one of these may be omitted.

Also, between the second substrate SUB2 and the display unit DC, the first color filter CF1, the second color filter CF2, and the third color filter CF3 overlap the entire surface of the non-display area PA in the thickness direction, and can be nested consecutively. The first color filter CF1, the second color filter CF2, and the third color filter CF3 may serve as light blocking members to prevent the non-display area PA from being viewed.

A sealant SL according to an embodiment may be positioned on the first insulating layer IL3. Components positioned on the first substrate SUB1 and components positioned on the second substrate SUB2 may be coupled through the sealant SL positioned in the non-display area PA.

The sealant SL may overlap the second spacer CS2 located in the non-display area PA. The second spacer CS2 may be positioned between the sealant SL and the second insulating layer IL4. The second spacer CS2 may be positioned on the same layer as the first spacer CS1 and the transmission layer TL.

Depending on the manufacturing process, the second spacer CS2 may be formed in the same process as the first spacer CS1 and the transmission layer TL. The second spacer CS2 according to an embodiment may be positioned between the second insulating layer IL4 and the filling layer FL. The second spacer CS2 may include the same material as the first spacer CS1 and the transmission layer TL, and may include, for example, the same type of scatterer SC. The second spacer CS2 may have the same height as each of the first spacer CS1 and the transmission layer TL in the thickness direction.

According to an embodiment, the transmission layer TL, the first spacer CS1, and the second spacer CS2 are formed through a single process, thus simplifying the manufacturing process and significantly saving time and cost incurred by the manufacturing process.

After the transmission layer TL, the first spacer CS1 and the second spacer CS2 according to an embodiment are manufactured to be positioned on the second substrate SUB2, they may be bonded to the first substrate SUB1.

On the second substrate SUB2, the color filters CF1, CF2, and CF3, the second insulating layer IL4, the third insulating layer IL5, the transmission layer TL, the first spacer CS1, and the second spacer CS2 are formed.

The components located on the second substrate SUB2 can perform a sintering process at high temperatures (for example, 200 degrees in Celsius (C.°) or more), and accordingly, the adhesion of the edges of the transmission layer TL and spacers CS1, CS2 and the flatness of the lower surface can be effectively improved.

Hereinafter, the display panel according to another embodiment will be described with reference to FIG. 4. Descriptions of components identical to those described in FIG. 3 will be omitted. A structure of the display unit DC according to an embodiment may be the same as the stacked structure of the display unit DC described with reference to FIG. 3. However, light emitted from the light emitting element ED according to the embodiment of FIG. 4 may be a mixture of blue light and green light.

The color conversion unit CC according to an embodiment may include a bank BK1 positioned on the encapsulation layer ENC.

The bank BK1 may define a first opening OP1, a second opening OP2, and a third opening OP3 overlapping pixel openings, respectively. The sizes of the first opening OP1, the second opening OP2, and the third opening OP3 may be different or the same. The first color conversion layer CCL1 may be positioned in the first opening OP1.

The first color conversion layer CCL1 may convert supplied light into red light. The first color conversion layer CCL1 may include quantum dots.

A first insulating layer IL3 may be positioned on the bank BK1 and the first color conversion layer CCL1. The first insulating layer IL3 may cover the bank BK1 and the first color conversion layer CCL1. The first insulating layer IL3 may include at least one of silicon nitride, silicon oxide, and silicon oxynitride. According to an embodiment, the first insulating layer IL3 may be omitted.

The filling layer FL may be positioned on the first insulating layer IL3. The filling layer FL may combine components positioned on the first substrate SUB1 and components positioned on the second substrate SUB2. One display panel may be formed through the filling layer FL. The filling layer FL may fill the second opening OP2 and the third opening OP3.

A first transmission layer TL1, a second transmission layer TL2, and a first spacer CS1 may be positioned on the filling layer FL. The first transmission layer TL1 may overlap the third opening OP3 in the thickness direction. The first transmission layer TL1 may be positioned in a portion corresponding to the blue light emitting area BLA in the space partitioned by the bank BK1. The first transmission layer TL1 may be formed on the second substrate SUB2 during the manufacturing process, and may be coupled to the first substrate SUB1 through the filling layer FL. The first transmission layer TL1 may have a tapered cross-section toward the first substrate SUB1.

The second transmission layer TL2 may overlap the second opening OP2 in the thickness direction. The second transmission layer TL2 may be positioned in a portion corresponding to the green light emitting area GLA in the space partitioned by the bank BK1. The second transmission layer TL2 may be formed on the second substrate SUB2 during the manufacturing process, and may be coupled to the first substrate SUB 1 through the filling layer FL. The second transmission layer TL2 may have a tapered cross-section toward the first substrate SUB1.

Each of the first transmission layer TL1 and the second transmission layer TL2 may include a scatterer SC. The first transmission layer TL1 and the second transmission layer TL2 may include the same type of scatterer SC. The scatterer SC may be one or more selected from the group consisting of SiO₂, BaSO₄, Al₂O₃, ZnO, ZrO₂, and TiO₂.

In the display panel according to the present embodiment, the first color conversion layer CCL1 color-converts the incident light to red light and emits it. In addition, light incident on the second transmission layer TL2 transmits through the second transmission layer TL2 without color conversion. Light incident on the first transmission layer TL1 transmits through the first transmission layer TL1 without color conversion.

According to an embodiment, light incident to the first transmission layer TL1 and the second transmission layer TL2 may be a mixture of blue light and green light. Light passing through the second transmission layer TL2 in the green light emission area GLA passes through the third color filter CF3, and thus high-purity green light may be emitted.

Light passing through the first transmission layer TL1 in the blue light emitting area BLA passes through the first color filter CF1, and high-purity blue light may be emitted.

The color conversion unit CC according to an embodiment includes the first spacer CS1. The first spacer CS1 may maintain a gap between components in a process of bonding the second substrate SUB2 and the first substrate SUB1. The first spacer CS1 may be positioned between the first insulating layer IL3 and the second insulating layer IL4. The first spacer CS1 may be positioned on the same layer as the first transmission layer TL1 and the second transmission layer TL2.

The first spacer CS1 may be formed in the same process as the first transmission layer TL1 and the second transmission layer TL2. The first spacer CS1, the first transmission layer TL1, and the second transmission layer TL2 may include the same material. The first spacer CS1, the first transmission layer TL1, and the second transmission layer TL2 may include the same scatterer SC. The height of the first spacer CS1 and the heights of the first transmission layer TL1 and the second transmission layer TL2 may be the same. The first spacer CS1 may have a tapered shape toward the first substrate SUB1.

When the first spacer CS1 and the first transmission layer TL1 (or the second transmission layer TL2) have a first height and a first scatterer content, the value of the first height multiplied by the first scatterer content is constant can be maintained. The first height may be 0.5 micrometers to 10 micrometers-for example, 1 micrometers to 5 micrometers. It is assumed that the first spacer CS1 and the first transmission layer TL1 have a height of 4 micrometers and a scatterer content of 3 wt %. In the case where the first spacer CS1 and the first transmission layer TL1 are modified to have a height of 3 micrometers, the first spacer CS1 and the first transmission layer TL1 can be modified to have a scatterer content of 4 wt %.

Within the range where the value of the height multiplied by scatterer content of the first spacer CS1 and the first transmission layer TL1 is maintained constant, the height and scatterer content of the first spacer CS1 and the first transmission layer TL1 can change.

The second insulating layer IL4 and the third insulating layer IL5 may be sequentially positioned on the first transmission layer TL1, the second transmission layer TL2, the first spacer CS1, and the filling layer FL. Each of the second insulating layer IL4 and the third insulating layer IL5 may include an inorganic material or an organic material.

Also, the color conversion unit CC may include a first color filter CF1, a second color filter CF2, and a third color filter CF3 positioned between the second substrate SUB2 and the display unit DC.

The first color filter CF1 may overlap the first transmission layer TL1 in the thickness direction. The first color filter CF1 transmits the blue light that has passed through the first transmission layer TL1 and absorbs light of other wavelengths, thereby increasing the purity of the blue light emitted to the outside of the display device.

The second color filter CF2 may overlap the first color conversion unit CCL1 in the thickness direction. The second color filter CF2 transmits the red light that has passed through the first color conversion layer CCL1, and absorbs light of other wavelengths, thereby increasing the purity of the red light emitted to the outside of the display device.

The third color filter CF3 may overlap the second transmission layer TL2 in the thickness direction. The third color filter CF3 transmits the green light that has passed through the second transmission layer TL2 and absorbs light of other wavelengths, thereby increasing the purity of the green light emitted to the outside of the display device.

The sealant SL according to an embodiment may overlap the second spacer CS2 positioned in the non-display area PA. The second spacer CS2 may be positioned between the sealant SL and the second insulating layer IL4. The second spacer CS2 may be positioned on the same layer as the first spacer CS1, the first transmission layer TL1, and the second transmission layer TL2.

Depending on the manufacturing process, the second spacer CS2 may be formed in the same process as the first spacer CS1, the first transmission layer TL1, and the second transmission layer TL2.

The second spacer CS2 according to an embodiment may be positioned between the second insulating layer IL4 and the filling layer FL. The second spacer CS2 may include the same material as the first spacer CS1, the first transmission layer TL1, and the second transmission layer TL2, and may include, for example, the same type of scatterer SC. The second spacer CS2 may have the same height as each of the first spacer CS1, the first transmission layer TL1, and the second transmission layer TL2 in the thickness direction.

According to an embodiment, since the first transmission layer TL1, the second transmission layer TL2, the first spacer CS1, and the second spacer CS2 are formed through one process, the manufacturing process is simplified, and the time and cost required for the manufacturing process can be significantly reduced.

According to one embodiment, the first transmission layer TL1, the second transmission layer TL2, the first spacer CS1, and the second spacer CS2 can be combined with the first substrate SUBI after being manufactured to be located on the second substrate SUB2.

On the second substrate SUB2, color filters CF1, CF2, and CF3, the second insulating layer IL4, the third insulating layer IL5, the first transmission layer TL1, the second transmission layer TL2, and the second transmission layer TL2 are provided. The first spacer CS1 and the second spacer CS2 are thus formed.

Components positioned on the second substrate SUB2 may perform a firing process at a high temperature (for example, 200 degrees in Celsius (C.°) or more), and thus the adhesion of the edges of the transmission layers TL1 and TL2, and the spacers CS1 and CS2 may be improved, the flatness of the lower surface can be effectively improved.

Hereinafter, a display panel according to still another embodiment will be described with reference to FIG. 5.

Descriptions of components identical to those described in FIG. 3 will be omitted.

Referring to FIG. 5, the color conversion unit CC may include the bank BK1 positioned on the encapsulation layer ENC.

The bank BK1 may define the first opening OP1, the second opening OP2, and the third opening OP3 overlapping the pixel openings in the thickness direction, respectively. The sizes of the first opening OP1, the second opening OP2, and the third opening OP3 may be different or the same, the transmission layer TL and the first spacer CS1 are disposed on the filling layer FL.

The transmission layer TL may overlap the third opening OP3 in the thickness direction. The transmission layer TL may be positioned in a portion corresponding to the blue light emitting area BLA in the space partitioned by the bank BK1. The transmission layer TL may be formed on the second substrate SUB2 during the manufacturing process, and may be coupled to the first substrate SUB1 through the filling layer FL. The transmission layer TL may have a tapered cross-section toward the first substrate SUB1.

A width of the transmission layer TL may be greater than a width of the third opening OP3. For example, the transmission layer TL may have a first surface facing the display unit DC, and the first surface may have a first width W1 in a direction parallel to the major surface of the first substrate SUB1. Also, an upper end of the third opening OP3 facing the transmission layer TL may have a second width W2. The first width W1 may be greater than the second width W2.

As shown in FIG. 5, the transmission layer TL may overlap at least a portion of the bank BK1 defining the third opening OP3 in the thickness direction. According to an embodiment, the first surface of the transmission layer TL may be disposed on the upper surface of the bank BK1. At least a portion of the transmission layer TL may be positioned on the first insulating layer IL3. A first surface of the transmission layer TL may contact the first insulating layer IL3.

Although the embodiments of the present invention have been described in detail above, the scope is not limited thereto, and various modifications and improvements of those skilled in the art using the basic concepts of the present invention defined in the following claims are also included in the scope of the present invention.

### DESCRIPTION OF SYMBOLS

DA: display area
PA: non-display area
SUB1, SUB2: substrate
ED: light emitting element
CCL1, CCL2: color conversion layer
TL: transmission layer
BK1: bank
FL: filling layer
CS1, CS2: spacer

1. A display device, comprising:
a substrate including a display area and a non-display area;
a transistor located on the substrate;
a light emitting element electrically connected to the transistor;
an encapsulation layer located on the light emitting element;
a bank located on the encapsulation layer and defining an opening therein;
a color conversion layer positioned within the opening;
a filling layer positioned on the bank and the color conversion layer; and
a transmission layer and a first spacer, which are disposed on the filling layer.

2. The display device of claim 1, wherein:
the opening includes a first opening, a second opening, and a third opening,
wherein the color conversion layer comprises:
a first color conversion layer located in the first opening and including quantum dots, and
a second color conversion layer positioned within the second opening and including quantum dots.

3. The display device of claim 2, wherein:
the transmission layer overlaps the third opening in a thickness direction of the substrate.

4. The display device of claim 2, wherein:
the filling layer is positioned in the third opening.

5. The display device of claim 1, wherein:
the transmission layer and the first spacer include a same type of scatterer.

6. The display device of claim 1, wherein:
the transmission layer and the first spacer have a same height in a thickness direction of the substrate.

7. The display device of claim 1, further comprising:
a second spacer positioned in the non-display area, and
a sealant overlapping the second spacer in a thickness direction of the substrate.

8. The display device of claim 7, wherein:
the second spacer has a same height as the transmission layer, and
the second spacer and the transmission layer include a same type of scatterer.

9. The display device of claim 7, further comprising:
an insulating layer positioned on the transmission layer, the first spacer, and the filling layer, and
a color filter positioned on the insulating layer.

10. The display device of claim 9, wherein:
the color filter comprises
a first color filter overlapping the transmission layer in the thickness direction;
a second color filter overlapping the first color conversion layer in the thickness direction; and
a third color filter overlapping the second color conversion layer in the thickness direction,
wherein the bank overlaps at least two of the first color filter, the second color filter, and the third color filter in the thickness direction.

11. The display device of claim 10, wherein:
at least one of the first spacer and the second spacer overlaps at least two of the first color filter, the second color filter, and the third color filter in the thickness direction.

12. A display device, comprising:
a substrate including a display area and a non-display area;
a transistor located on the substrate;
a light emitting element electrically connected to the transistor;
an encapsulation layer located on the light emitting element;
a bank located on the encapsulation layer and defining an opening therein;
a color conversion layer positioned within the opening;
a filling layer positioned on the bank and the color conversion layer; and
a first transmission layer, a second transmission layer, and a first spacer, which are disposed on the filling layer.

13. The display device of claim 12, wherein:
the opening includes a first opening, a second opening, and a third opening, and
the color conversion layer includes a first color conversion layer positioned within the first opening.

14. The display device of claim 13, wherein:
the second opening overlaps the second transmission layer in a thickness direction of the substrate, and
the third opening overlaps the first transmission layer in the thickness direction.

15. The display device of claim 13, wherein:
the filling layer fills the second opening and the third opening.

16. The display device of claim 13, further comprising:
an insulating layer disposed on the first transmission layer, the second transmission layer, and the filling layer, and
a color filter positioned on the insulating layer.

17. The display device of claim 13, wherein:
the first transmission layer, the second transmission layer, and the first spacer have a same height and include a same type of scatterer.

18. The display device of claim 17, further comprising:
a second spacer located in the non-display area, and
a sealant overlapping the second spacer in a thickness direction of the substrate.

19. The display device of claim 18, wherein:
the second spacer has the same height as the first spacer and includes the same type of scatterer.

20. The display device of claim 13, wherein:
the light emitting element is configured to emit a mixture of blue light and green light.
